(19) United States
(12) Patent Application Publication
(10) Pub. No.: US 2014/0339975 A1
(43) Pub. Date: Nov. 20, 2014

(54) SLIDE ASSEMBLY

(71) Applicant: HON HAI PRECISION INDUSTRY CO., LTD., New Taipei (TW)

(72) Inventors: CHEN-LU FAN, New Taipei (TW); LI-PING CHEN, New Taipei (TW)

(73) Assignee: HON HAI PRECISION INDUSTRY CO., LTD., New Taipei (TW)

(21) Appl. No.: 14/138,326

(22) Filed: Dec. 23, 2013

(30) Foreign Application Priority Data
May 14, 2013 (TW) 102116971

(51) Int. Cl. H05K 5/02; A47B 88/04

(52) U.S. Cl. CPC H05K 5/0217; A47B 88/04
USPC 312/334.1

(57) ABSTRACT

A slide assembly includes a first rail, a second rail, a third rail, and a mounting rack. The first rail includes a first path defined along a longitudinal direction of the first rail. The second rail is movably located in the first path of the first rail. The second rail includes a second path defined a longitudinal direction of the second rail. The mounting rack comprising a base plate and two brackets vertically fixed to the base plate. The first rail is mounted to one of the two brackets and the second rail is mounted to another of the two brackets. The third rail is movably located in the second path of the second rail and configured for pulling a chassis of a computer when the third rail moves in the second path of the second rail.

### REFERENCE TO RELATED APPLICATIONS

This application claims all benefits accruing under 35 U.S.C. §119 from Taiwan Patent Application No. 102116971 filed on May 14, 2013 in the Taiwan Intellectual Property Office, the contents of the Taiwan Application are hereby incorporated by reference.

### BACKGROUND

1. Technical Field

The present disclosure generally relates to slide assemblies.

2. Description of Related Art

Slide assemblies are used in the drawers of furniture or the chassis on the computer rack to support the sliding of the drawer or the chassis. The slide assemblies are required to provide accurate and smooth guiding. However, the conventional slide assemblies have complicated structures and may not be reliable.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a slide assembly.

FIG. 2 is similar to FIG. 1, but viewed from another aspect.

FIG. 3 is an enlarged view of a circled portion III of FIG. 1.

FIG. 4 is an assembled view of the slide assembly of FIG. 1.

FIG. 5 is an enlarged view of a circled portion V of FIG. 4.

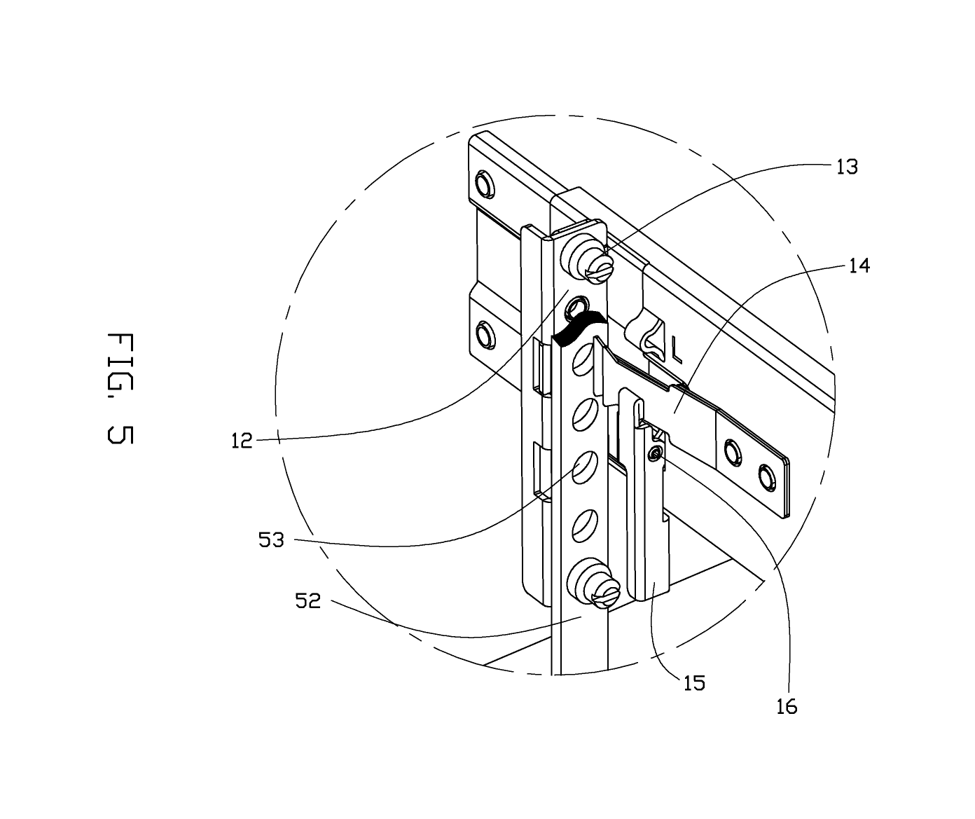

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

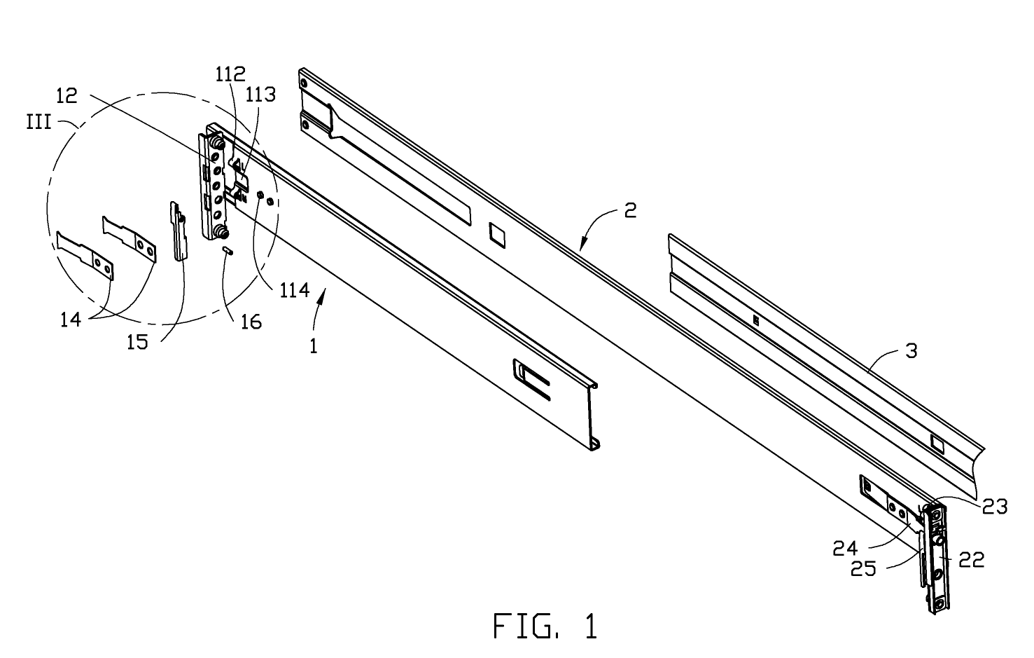

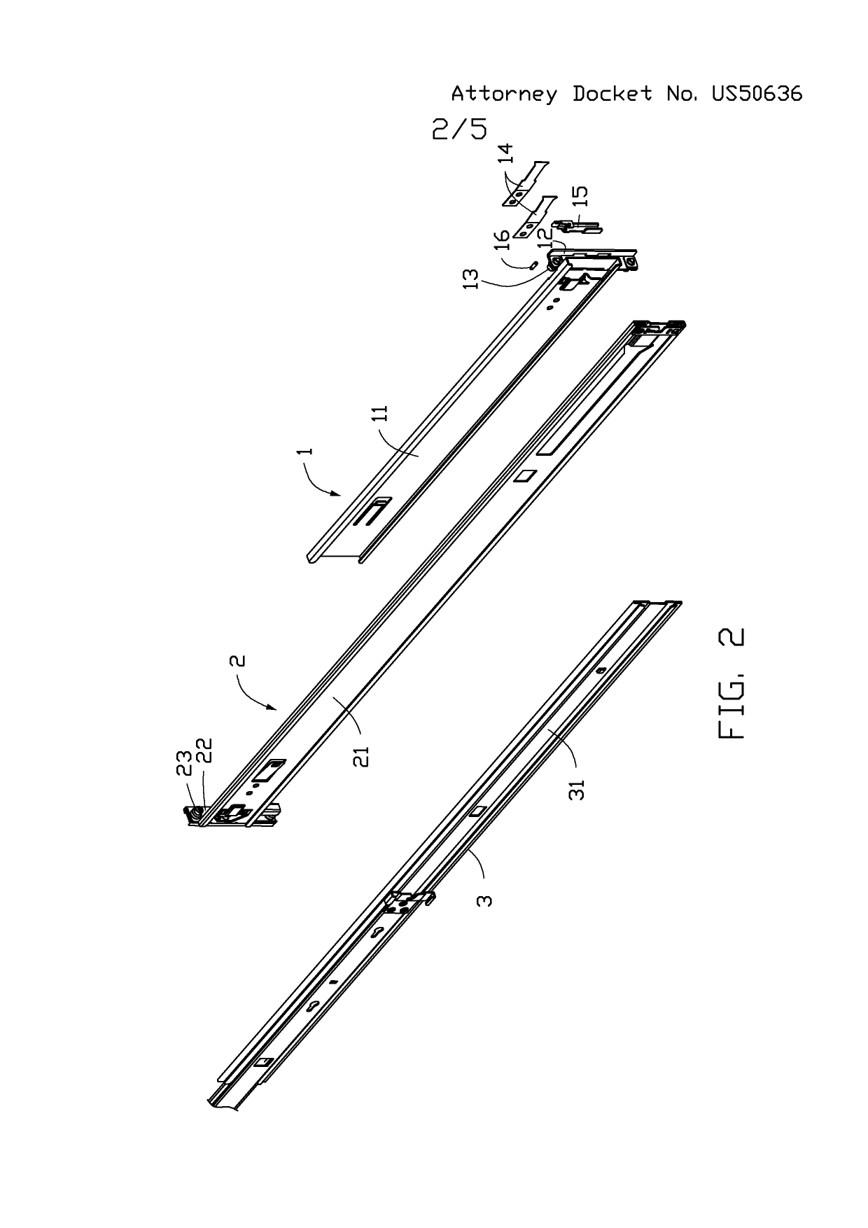

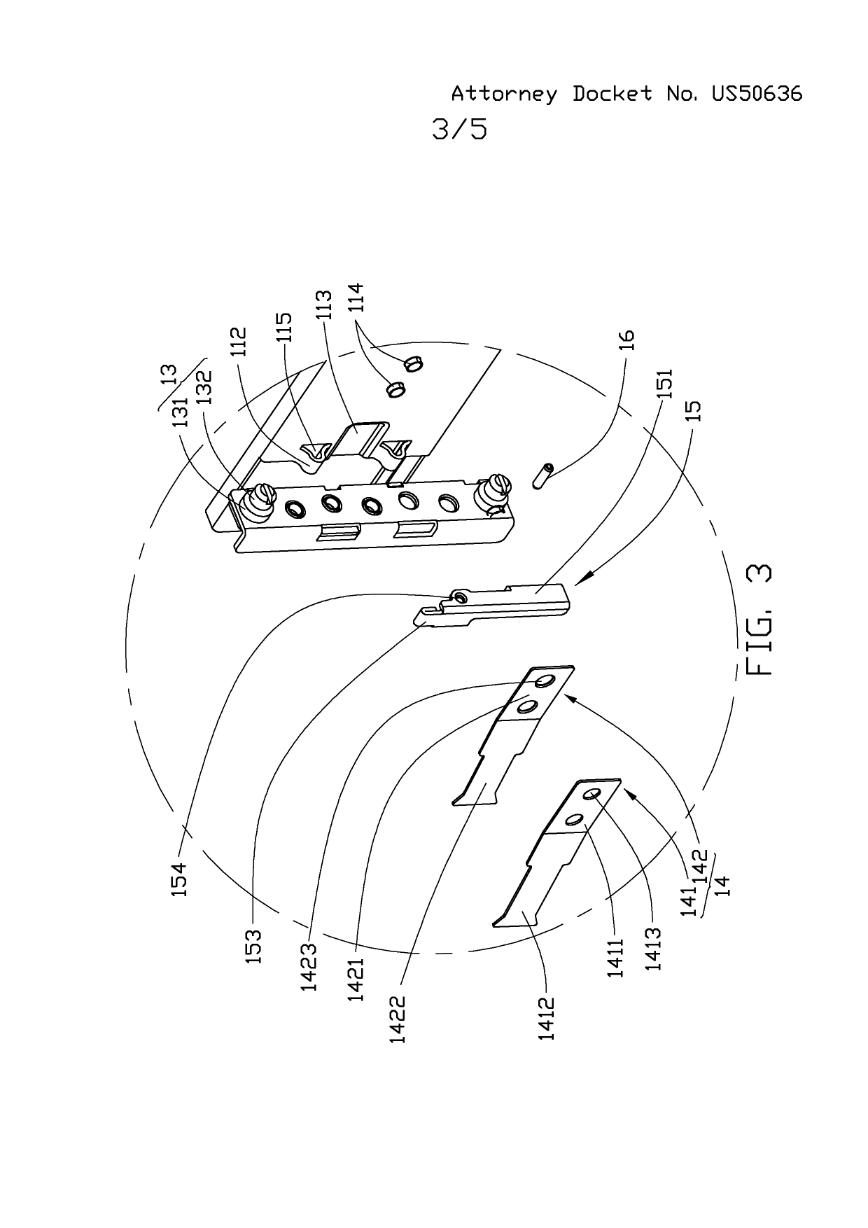

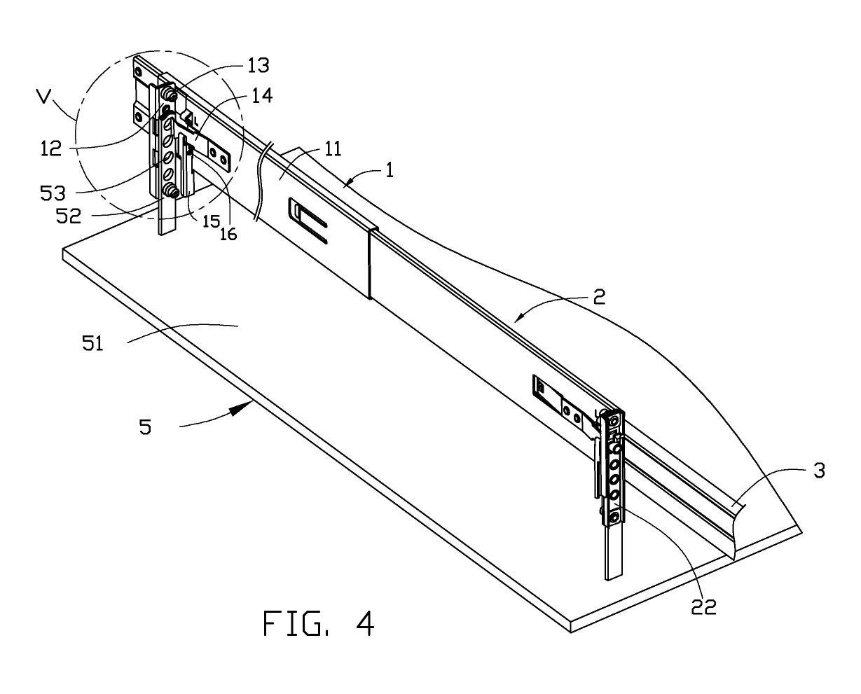

FIGS. 1-4 show an embodiment of a slide assembly. The slide assembly includes a first rail 1, a second rail 2, a third rail 3, and a mounting rack 5. The second rail 2 is movably mounted to the first rail 1. The third rail 3 is movably mounted to the second rail 2. The first rail 1 and the second rail 2 are mounted to the mounting rack 5.

The mounting rack 5 includes a base plate 51 and a pair of brackets 52. The two brackets 52 are vertically fixed to an upper surface of the base plate 51. The first rail 1 is mounted to one of the two brackets 52 and the second rail 2 is mounted to another of the two brackets 52. Each of the two brackets 52 defines a plurality of mounting holes 53. The plurality of mounting holes 53 are arranged in a straight line along a longitudinal direction of the bracket 52.

The first rail 1 includes a first path 11 defined along a longitudinal direction of the first rail 1. A first installation member 12 is located adjacent to an end of the first rail 1. A resisting member 14 is located corresponding to the first installation member 12. At least one installation portion 13 protrudes laterally from the first installation member 12.

The first installation portion 13 extends through the mounting hole 53 of one of the two brackets 52, so that the first rail 1 is mounted to the one of the two brackets 52. The installation portion 13 extends towards the resisting member 14. The installation portion 13 includes a first post 131 and a second post 132. The first post 131 extends from the first installation member 12 and the second post 132 extends from the first post 132. A diameter of the first post 131 is greater than that of the second post 132.

The resisting member 14 includes a first resisting piece 141 and a second resisting piece 142.

The first resisting piece 141 includes a first fixing portion 1411 and a first resilient portion 1412. The first resilient portion 1412 extends longitudinally from the first fixing portion 1411 and is bent an angle relative to the first fixing portion 1411. The first resilient portion 1412 is located adjacent to the installation portion 13. The first fixing portion 1411 defines at least one first fixing hole 1413.

The second resisting piece 142 includes a second fixing portion 1421 and a second resilient portion 1422. The second resilient portion 1422 extends longitudinally from the second fixing portion 1421 and is bent an angle relative to the second fixing portion 1421. The second resilient portion 1422 is located adjacent to the installation portion 13. The second fixing portion 1421 defines at least one second fixing hole 1423.

A length of the second fixing portion 1421 is substantially the same as that of the first fixing portion 1411. A length of the second resilient portion 1422 is less than that of the first resilient portion 1412.

At least one first mounting post 114 protrudes perpendicularly from the first rail 1. The first fixing hole 1413 is aligned with the second fixing hole 1423. The first mounting post 114 extends successively through the second fixing hole 1423 and the first fixing hole 1413, so that the first resisting piece 141 and the second resisting piece 142 are mounted to the first rail 1. The second resisting pieced 142 is sandwiched between the first resisting piece 141 and the first rail 1.

The first rail 1 includes a recess portion 113. The recess portion 113 is located adjacent to an end of the first rail 1 and is located between the first installation member 12 and the first mounting post 114. The first resilient portion 1412 and the second resilient portion 1422 are engaged with the recess portion 113 of the first rail 1. A pivot portion 112 protrudes from the first rail 1 and is located adjacent to the recess portion 113. The pivot portion 112 defines a first pivot hole 115.

A pressing member 15 includes a handle 151 and a pressing portion 153. The pressing member 15 defines a second pivot hole 154. The second pivot hole 154 of the pressing member 15 is aligned with the first pivot hole 115 of the pivot portion 112. A pivot post 16 extends through the first pivot hole 115 and the second pivot hole 154, so that the pressing member 15 is pivotally mounted to the first rail 1. When the pressing member 15 moves to a locked position, the pressing portion 154 presses the first resilient portion 1412 of the first resisting piece 141. When the pressing member 15 moves to an unlocked position, the pressing portion 154 releases the pressure force exerted to the first resilient portion 1412 of the first resisting piece 141.

The second rail 2 is movably located in the first path 11 of the first rail 1. The second rail 2 includes a second path 21 defined along a longitudinal direction of the second rail 2. A second installation member 22 is located adjacent to an end of the second rail 2. A second resisting member 24 is located corresponding to the second installation member 22. At least one second installation portion 23 protrudes laterally from the second installation member 22.

In one embodiment, the second installation member 22 is similar to the installation member 12, the second resisting member 24 is similar to the resisting member 14, and the second installation portion 23 is similar to the installation portion 13. The second rail 2 is mounted to one of the two brackets 52 in a principle substantially identical to the first rail 1 mounted to another one of the two brackets 52.

The third rail 3 is movably located in the second path 21 of the second rail 2. The third rail 3 includes a third path 31 defined along a longitudinal direction of the third rail 3. A chassis (not shown) of a computer may be attached to the third rail 3, so that the computer may be pulled by the third rail 3 when the third rail 3 moves in the second path 21 of the second rail 2.

In one embodiment, a length of the second rail 2 is greater than that of the first rail 1, and is substantially the same as that of the third rail 3.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A slide assembly, comprising:
a first rail comprising a first path defined along a longitudinal direction of the first rail;
a second rail movably located in the first path of the first rail, the second rail comprising a second path defined a longitudinal direction of the second rail;
a mounting rack comprising a base plate and two brackets vertically fixed to the base plate, wherein the first rail is mounted to one of the two brackets and the second rail is mounted to another one of the two brackets;
a third rail movably located in the second path of the second rail and configured for pulling a chassis of a computer when the third rail moves in the second path of the second rail.

2. The slide assembly of claim 1, further comprising an installation member located adjacent to an end of the first rail, wherein each of the two brackets defines a mounting hole, an installation portion protrudes laterally from the installation member and extends through the mounting hole thereby mounting the first rail to one of the two brackets.

3. The slide assembly of claim 2, wherein the installation portion comprises a first post extending from the installation member and a second post extending from the first post, a diameter of the first post is greater than a diameter of the second post.

4. The slide assembly of claim 2, further comprising a first resisting piece mounted to the first rail and correspondingly located relative to the installation member, wherein the first resisting piece comprises a first fixing portion mounted to the firs rail and a first resilient portion extending longitudinally from the first fixing portion, the first resilient portion is bent at an angle relative to the first fixing portion.

5. The slide assembly of claim 4, wherein the first rail comprises a recess portion, the first resilient portion is engaged with the recess portion of the first rail.

6. The slide assembly of claim 5, wherein the first fixing portion defines a first fixing hole, a first mounting post protrudes from the first rail and extends through the first fixing hole thereby mounting the first resisting piece to the first rail.

7. The slide assembly of claim 6, further comprising a second resisting piece having substantially a same shape as the first resisting piece, wherein the second resisting piece is sandwiched between the first resisting piece and the first rail.

8. The slide assembly of claim 6, further comprising a pressing member pivotally mounted to the first rail, the pressing member comprising a pressing portion, wherein when the pressing member is moved to a pre-set position, the pressing member presses the first resilient portion of the first resisting piece.

9. The slide assembly of claim 8, wherein a pivot portion protrudes from the first rail, the pivot portion defines a first pivot hole, the pressing member defines a second pivot hole, and a pivot post extends through the first pivot hole and the second pivot hole.

10. The slide assembly of claim 1, wherein a length of the second rail is greater than a length of the first rail and is substantially the same as a length of the third rail.

11. A slide assembly, comprising:
a first rail comprising a recess portion and a first path defined along a longitudinal direction of the first rail;
a first resisting piece mounted to the first rail and comprising a resilient portion engaged with the recess portion of the first rail;
a second rail movably located in the first path of the first rail, the second rail comprising a second path defined a longitudinal direction of the second rail; and
a third rail movably located in the second path of the second rail and configured for pulling a chassis of a computer when the third rail moves in the second path of the second rail.

12. The slide assembly of claim 11, further comprising a mounting rack, the mounting rack comprising a base plate and two brackets vertically fixed to the base plate, wherein the first rail is mounted to one of the two brackets and the second rail is mounted to another one of the two brackets.

13. The slide assembly of claim 12, further comprising an installation member located adjacent to an end of the first rail, wherein each of the two brackets defines a mounting hole, an installation portion protrudes laterally from the installation member and extends through the mounting hole thereby mounting the first rail to one of the two brackets.

14. The slide assembly of claim 13, wherein the installation portion comprises a first post extending from the installation member and a second post extending from the first post, a diameter of the first post is greater than a diameter of the second post.

15. The slide assembly of claim 13, wherein the first resisting piece is correspondingly located relative to the installation member, the first resisting piece comprises a first fixing portion mounted to the firs rail, the first resilient portion extends longitudinally from the first fixing portion and is bent an angle relative to the first fixing portion.

16. The slide assembly of claim 15, wherein the first fixing portion defines a first fixing hole, a first mounting post protrudes from the first rail and extends through the first fixing hole thereby mounting the first resisting piece to the first rail.

17. The slide assembly of claim 16, further comprising a second resisting piece having substantially a same shape as the first resisting piece, wherein the second resisting piece is sandwiched between the first resisting piece and the first rail.

18. The slide assembly of claim 16, further comprising a pressing member pivotally mounted to the first rail, the pressing member comprising a pressing portion, wherein when the pressing member is moved to a pre-set position, the pressing member presses the first resilient portion of the first resisting piece.

19. The slide assembly of claim 18, wherein a pivot portion protrudes from the first rail, the pivot portion defines a first pivot hole, the pressing member defines a second pivot hole, and a pivot post extends through the first pivot hole and the second pivot hole.
